(19) United States
(12) Patent Application Publication
(10) Pub. No.: US 2024/0053774 A1
(43) Pub. Date: Feb. 15, 2024

(54) VACUUM MASS FLOW CONTROL APPARATUS AND CONTROL METHOD THEREOF

(71) Applicants: Festo (China) Production Ltd., Shanghai (CN); FESTO SE & CO. KG, Esslingen (DE)

(72) Inventors: He ZUO, Shanghai (CN); Shuangshuang LIU, Shanghai (CN); Chunge WANG, Shanghai (CN); Quan ZOU, Shanghai (CN)

(21) Appl. No.: 18/447,921

(22) Filed: Aug. 10, 2023

(30) Foreign Application Priority Data
Aug. 11, 2022 (CN) 202210962105.X

(51) Int. Cl. G05D 7/06

(52) U.S. Cl. CPC G05D 7/0635; G05D 7/0682

(57) ABSTRACT

A vacuum mass flow control apparatus and a control method thereof. The apparatus includes: a housing; a first flow channel disposed in the housing and having a first starting end and a first terminating end; a first sensor for collecting a signal of fluid in the first flow channel; a second flow channel disposed in the housing and having a second starting end and a second terminating end; a second sensor for collecting a vacuum flow rate in the second flow channel; a venturi tube having an inlet end, an outlet end and a negative pressure suction port; a regulating valve for regulating a flow-through cross-sectional area of the first flow channel; and a controller electrically connected to the regulating valve, the first sensor and the second sensor. The present disclosure improves structural integration, greatly reduces structural volume, and realizes real-time precise regulation in terms of control.

### CROSS-REFERENCE TO RELATED APPLICATIONS

This application claims priority to Chinese Patent Application No. 202210962105.X, filed on Aug. 11, 2022, which is hereby incorporated by reference in its entirety.

### TECHNICAL FIELD

The present disclosure relates to the technical field of semiconductor equipments, and particularly to a vacuum mass flow control apparatus and a control method thereof.

### BACKGROUND

As the semiconductor industry upgrades and equipment iterates, there are new requirements for vacuum flow control in the gas circuit cycle.

The current technical solution of the vacuum flow control for gas path circulation is that a manual pressure regulating valve, a switching valve, a vacuum generator and a mass flow sensor are combined to form a system. The system substantially allows for vacuum mass flow control, however, it has many inconveniences in its use.

Firstly, the current system is only possible to vary the vacuum mass flow rate by means of manual adjustment, which does not allow for high regulation accuracy, nor for real-time control, nor for precise control, nor for real-time monitoring of the vacuum mass flow rate. Secondly, various parts of the current system are independent from each other and need to be connected through pipelines, they take up a lot of space and are not conducive to arrangement, and they are expensive to manufacture and install and are not easy to maintain.

### SUMMARY

In order to overcome the defects of the prior art, the embodiments of the present disclosure provide a vacuum mass flow control apparatus and a control method thereof, which is small and highly integrated in terms of structure, and achieves real-time and precise regulation in terms of control.

The specific technical solutions of the embodiments of the present disclosure are as follows:

A vacuum mass flow control apparatus, including a housing, a first flow channel, a first sensor, a second flow channel, a second sensor, a venturi tube, a regulating valve, and a controller. The first flow channel is disposed in the housing and has a first starting end for being connected to a positive pressure gas source and a first terminating end. The first sensor is capable of collecting a signal of fluid in the first flow channel. The second flow channel is disposed in the housing and has a second starting end for being connected to a peripheral device and a second terminating end. The second sensor is capable of collecting a vacuum flow rate in the second flow channel. The venturi tube has an inlet end, an outlet end and a negative pressure suction port. When a positive pressure fluid flowing out of the first terminating end flows through the venturi tube via the inlet end, it sucks a negative pressure fluid at the second terminating end into the venturi tube via the negative pressure suction port and then flows out with the negative pressure fluid via the outlet end. The regulating valve is capable of regulating a flow-through cross-sectional area of the first flow channel. The controller is electrically connected to the regulating valve, the first sensor and the second sensor.

In an exemplary embodiment, the controller is configured to: receive a target vacuum flow rate value and compare the target vacuum flow rate value with a vacuum flow rate value detected by the second sensor; and regulate, when a difference between the target vacuum flow rate value and the detected vacuum flow rate value is greater than a preset difference, an opening degree of the regulating valve based on the signal detected by the first sensor and a current opening degree of the regulating valve, until the difference is within a preset difference range.

In an exemplary embodiment, the first sensor is a pressure sensor, the regulating valve is a piezoelectric proportional valve, and the controller regulates the opening degree of the piezoelectric proportional valve by regulating a duty ratio of the piezoelectric proportional valve.

In an exemplary embodiment, a first connecting member is disposed in the housing, a hollow cavity is provided in the first connecting member to form the first flow channel, and a position detected by the first sensor is located upstream of the regulating valve in a fluid flowing direction.

In an exemplary embodiment, a branch flow channel in communication with the first flow channel is disposed in the first connecting member. An open end of the branch flow channel is in communication with the first flow channel, and the other end thereof is a closed end. The first sensor is mounted in the branch flow channel by means of sealing.

In an exemplary embodiment, a second connecting member is disposed in the housing, and the first connecting member is in communication with the regulating valve through the second connecting member.

In an exemplary embodiment, a third connecting member is disposed in the housing, a hollow cavity is provided in the third connecting member to form the second flow channel, and the second sensor is disposed in the second flow channel.

In an exemplary embodiment, a fourth connecting member is disposed in the housing. A hollow main cavity and a bypass cavity in communication with the main cavity are provided in the fourth connecting member. The main cavity is connected to the first terminating end of the first flow channel, and the venturi tube is sealingly mounted in the main cavity, and the bypass cavity is connected to the second terminating end of the second flow channel.

In an exemplary embodiment, the venturi tube includes a first portion and a second portion which are sealingly disposed in the main cavity, with a converge gap formed therebetween and opposite to the bypass cavity.

In an exemplary embodiment, a flow-through cross-sectional area of the first terminating end is smaller than that of the bypass cavity and larger than a minimum flow-through cross-sectional area of the venturi tube.

In an exemplary embodiment, the controller includes a circuit board disposed close to one side of the housing, and the side of the housing close to the circuit board is provided with a first dip switch and a second dip switch for switching between different signal input and output modes.

A vacuum mass flow control method based on the vacuum mass flow control apparatus aforementioned, including:
receiving a target vacuum flow rate value and comparing the target vacuum flow rate value with a vacuum flow rate value detected by the second sensor;
regulating, when a difference between the target vacuum flow rate value and the detected vacuum flow rate value is greater than a preset difference, an opening degree of the regulating valve based on the signal detected by the first sensor and a current opening degree of the regulating valve; and
controlling, when the difference is within a preset difference range, the regulating valve to stop regulating the opening degree.

In an exemplary embodiment, the first sensor is a pressure sensor, and the regulating valve is a piezoelectric proportional valve. The step of regulating the opening degree of the regulating valve based on the signal detected by the first sensor and the current opening degree of the regulating valve includes:
Sending, by the controller, a PWM drive signal to the piezoelectric proportional valve; and
regulating the opening degree of the piezoelectric proportional valve by regulating a duty ratio of the piezoelectric proportional valve.

The technical solutions of the present disclosure have the following remarkable advantageous effects:

According to the present disclosure, the venturi tube is provided to replace an entire vacuum generator, and the first flow channel for flowing the positive pressure fluid, the second flow channel for flowing the negative pressure fluid, the first sensor for collecting the signal of fluid in the first flow channel, the second sensor for collecting the vacuum flow rate in the second flow channel, the venturi tube, the regulating valve for regulating the flow-through cross-sectional area of the first flow channel, and the controller are designed to be integrated, and are integrally disposed in a same housing, so that the apparatus is small and highly integrated, takes up less space when installed, is conducive to arrangement, is cheaper to manufacture and install, and is easier to maintain.

In addition, in terms of control, the opening degree of the regulating valve is regulated mainly based on feedback values from the first sensor and the second sensors, so as to realize real-time control and precise regulation of the vacuum mass flow rate, and to feed back the real-time vacuum flow rate value.

With reference to the following description and drawings, specific embodiments of the present disclosure are disclosed in detail, and the ways in which the principle of the present disclosure can be adopted are pointed out. It should be understood that the embodiments of the present disclosure are not limited in scope thereby. The embodiments of the present disclosure include many changes, modifications and equivalents within the spirit and clauses of the appended claims. Features described and/or illustrated for one embodiment may be used in one or more other embodiments in the same or similar way, combined with features in other embodiments, or substituted for features in other embodiments.

### BRIEF DESCRIPTION OF THE DRAWINGS

The drawings described here are intended only to explain the present disclosure and do not limit the scope of the present disclosure in any way. In addition, the shapes and proportional dimensions of the components in the drawings are only schematic to facilitate understanding of the present disclosure, rather than specifically limiting the shapes and proportional dimensions of the components in the present disclosure. Under the teaching of the present disclosure, those skilled in the art can choose a variety of possible shapes and proportional sizes to implement the present disclosure according to specific conditions.

FIG. 1 is a stereo diagram of a vacuum mass flow control apparatus according to an embodiment of the present disclosure;

FIG. 2 is a structural diagram of a side of a housing of a vacuum mass flow control apparatus according to an embodiment of the present disclosure;

FIG. 3 is a distribution diagram of various parts inside a housing of a vacuum mass flow control apparatus according to an embodiment of the present disclosure;

FIG. 4 is a schematic diagram of flow channels in a vacuum mass flow control apparatus according to an embodiment of the present disclosure;

FIG. 5 is a cross-sectional view taken along line A-A at I in FIG. 3;

FIG. 6 is a schematic diagram at II in FIG. 3, illustrating an venturi tube and other structures;

FIG. 7 is a stereo diagram of a venturi tube according to an embodiment of the present disclosure;

FIG. 8 is a schematic diagram of working principle of a vacuum mass flow control apparatus according to an embodiment of the present disclosure; and

FIG. 9 is a flowchart of steps of a vacuum mass flow control method according to an embodiment of the present disclosure.

### REFERENCE NUMERALS IN THE DRAWINGS

10: housing;
20: first connecting member; 21: first starting end; 22: branch flow channel;
23: first sealing ring; 24: first terminating end; 200: first flow channel;
30: third connecting member; 31: second starting end; 300: second flow channel;
40: wire harness; 41: groove; 50: second sensor;
60: fourth connecting member; 61: main cavity; 62: bypass cavity;
63: second sealing ring; 70: second connecting member; 80: regulating valve;
90: controller; 91: connector; 92: first dip switch; 93: second dip switch; 94: first sensor;
100: venturi tube; 110: inlet end; 120: outlet end; 130: negative pressure suction port;
101: snap; 102: first portion; 103: second portion.

### DETAILED DESCRIPTION

The details of the present disclosure can be understood more clearly in conjunction with the drawings and the description of the specific embodiments of the present disclosure. However, the specific embodiments of the present disclosure described here are only for the purpose of explaining the present disclosure, and cannot be understood as limitations to the present disclosure in any way. Under the teaching of the present disclosure, those skilled in the art can conceive any possible variations based on the present disclosure, which should be regarded as belonging to the scope of the present disclosure. It should be noted that when an element is referred to be ‘disposed on’ another element, it may be directly on another element or there may be an intervening element. When an element is considered to be ‘connected to’ another element, it may be directly connected to another element or there may be also an intervening element. The term ‘mounting’ or ‘connection’ should be understood in a broad sense; for example, it may be a mechanical or electrical connection, or an internal communication between two elements; it may also be a direct connection, or an indirect connection through an intermediate medium. Those skilled in the art can understand the specific meanings of the above terms according to specific conditions. The terms ‘vertical’, ‘horizontal’, ‘upper’, ‘lower’, ‘left’ and ‘right’ and similar expressions used herein are only for the purpose of illustration, and do not represent a unique embodiment.

Unless otherwise defined, all technical and scientific terms used herein have the same meaning as those commonly understood by those skilled in the technical field of the present disclosure. The terms used in the specification of the present disclosure are only for the purpose of describing the specific embodiments and are not intended to limit the present disclosure. The term ‘and/or’ used herein includes any and all combinations of one or more associated listed items.

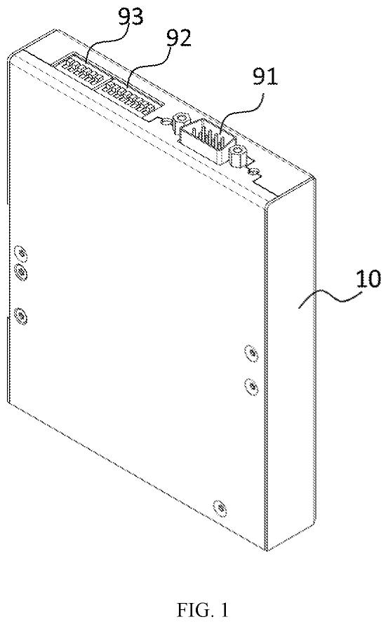

Referring to FIGS. 1 to 7, embodiments of the present disclosure provide a vacuum mass flow control apparatus, which may include a housing 10, a first flow channel 200, a first sensor 94, a second flow channel 300, a second sensor 50, a venturi tube 100, a regulating valve 80, and a controller 90. The first flow channel 200 is disposed in the housing 10, and has a first starting end 21 for being connected to a positive pressure gas source and a first terminating end 24. The first sensor 94 is configured to collect a signal of fluid in the first flow channel 200. The second flow channel 300 is disposed in the housing 10, and has a second starting end 31 for being connected to a peripheral device and a second terminating end. The second sensor 50 is configured to collect a vacuum flow rate in the second flow channel 300. The venturi tube 100 has an inlet end 110, an outlet end 120 and a negative pressure suction port 130. When a positive pressure fluid flowing out of the first terminating end 24 flows through the venturi tube 100 via the inlet end, it sucks a negative pressure fluid at the second terminating end into the venturi tube 100 via the negative pressure suction port 130 and then flows out with the negative pressure fluid through the outlet end 120. The regulating valve 80 is configured to regulate a flow-through cross-sectional area of the first flow channel 200. The controller 90 is electrically connected to the regulating valve 80, the first sensor 94, and the second sensor 50.

In the embodiments of the present disclosure, the venturi tube 100 is provided to replace an entire vacuum generator, and the first flow channel 200 for flowing the positive pressure fluid, the second flow channel 300 for flowing the negative pressure fluid, the first sensor 94 for collecting the signal of fluid in the first flow channel 200, the second sensor 50 for collecting the vacuum flow rate in the second flow channel 300, the venturi tube 100, the regulating valve 80 for regulating the flow-through cross-sectional area of the first flow channel 200, and the controller 90 are designed to be integrated, and are integrally disposed in the same housing 10, so that the apparatus of the present disclosure is small and highly integrated, takes up less space when installed, is conducive to arrangement, is cheaper to manufacture and install, and is easier to maintain.

In the embodiments of the present disclosure, the regulating valve 80 electrically connected to the controller 90 is provided to replace the manual pressure regulating valve in the prior art, and the first sensor 94 for collecting the signal of fluid in the first flow channel 200 and the second sensor 50 for collecting the vacuum flow rate in the second flow channel 300 are provided.

During use, the controller 90 receives a target vacuum flow rate value, compares the target vacuum flow rate value with a vacuum flow rate value detected by the second sensor 50, and regulate, when a difference between the target vacuum flow rate value and the detected vacuum flow rate value is greater than a preset difference, an opening degree of the regulating valve 80 based on the signal collected by the first sensor 94 and a current opening degree of the regulating valve 80, until the difference is within a preset difference range.

On the whole, in terms of control, the vacuum mass flow control apparatus of the present disclosure mainly regulates the opening degree of the regulating valve 80 based on feedback values from the first sensor 94 and the second sensor 50, so as to realize real-time control and precise regulation of the vacuum mass flow rate, and to feed back the real-time vacuum flow rate value.

The vacuum mass flow control apparatus of the present disclosure will be described in detail with reference to the drawings and the specific embodiments.

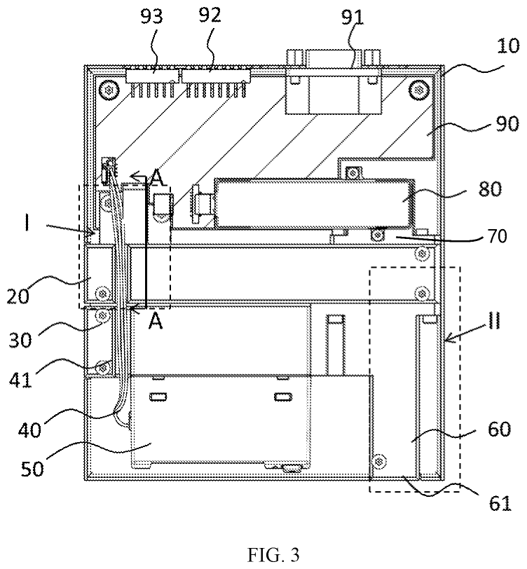

As illustrated in FIG. 3, in embodiments of the present disclosure, the core functional components integrated in the housing 10 of the vacuum mass flow control apparatus mainly include the first sensor 94, the second sensor 50, the venturi tube 100, the regulating valve 80, the controller 90, etc.

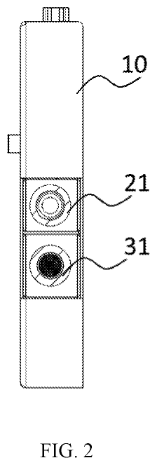

Referring to FIGS. 1 and 2, in the embodiments, the housing 10 may be a hollow structure with a predetermined size. Specifically, the shape and size of the housing 10 may be varied depending on the actual application scenarios and adaptation environments, which are not specifically limited herein. The size of the housing 10 is equivalent to that of the entire vacuum mass flow control apparatus. Compared with the current vacuum mass flow control apparatus adopting one-to-one connection through pipelines or the like, the housing 10 of the present disclosure is considerably reduced in size.

The housing 10 may be provided with a connector 91 for connecting an external device. Specifically, the number and functions of the connectors 91 may be determined according to functional requirement of the actual product, which are not specifically limited herein. For example, the connector 91 may be an interface for communicating with the external device, so as to input a signal to the vacuum mass flow control apparatus or output a signal from the vacuum mass flow control apparatus to the outside. Alternatively, the connector 91 may be an interface for supplying power to the vacuum mass flow control apparatus, or an interface with any other function, or an integrated interface for realizing the plurality of functions described above.

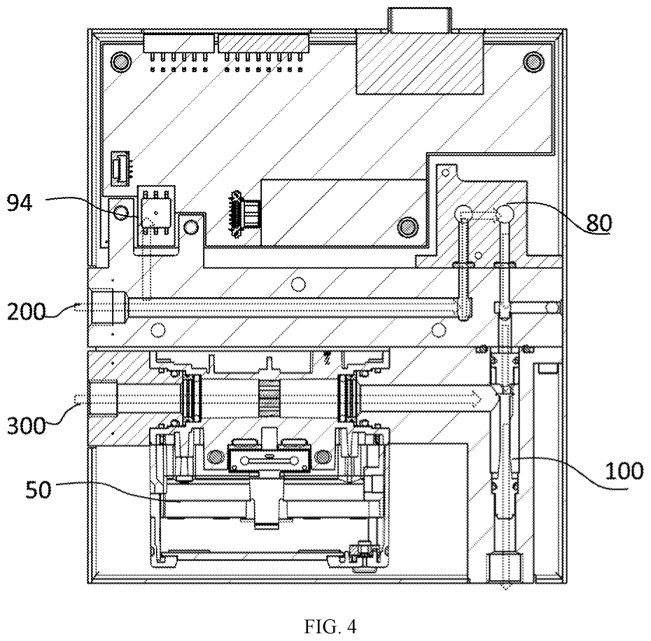

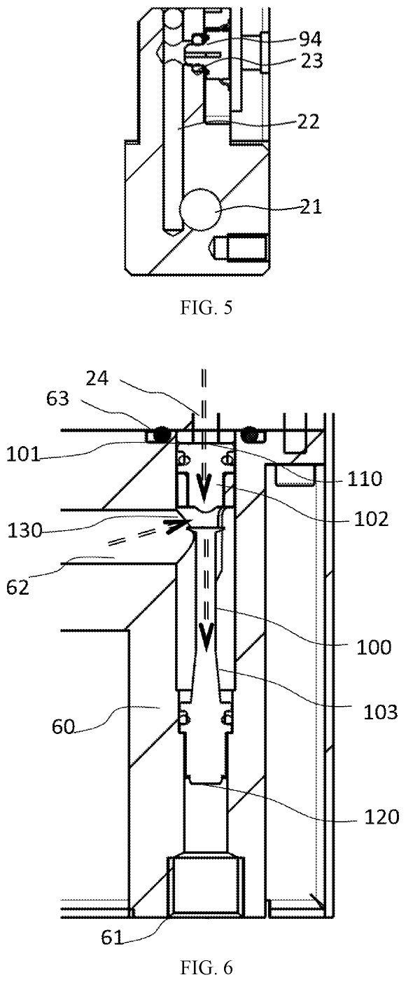

Referring to FIGS. 4 and 5, in the embodiments, the first sensor 94 is mainly used to collect a signal of fluid in the first flow channel 200. Specifically, the first sensor 94 may be a flow rate sensor, or a pressure sensor, or any other sensor capable of detecting the fluid flow rate in the first flow channel 200.

Specifically, in the embodiments of the present disclosure, when the first sensor 94 is a pressure sensor, it specifically may be an IC chip-level sensor with a very small size and occupying very little space in the housing 10, which is advantageous to the miniaturization design of the entire housing 10. In the following embodiments of the present disclosure, the first sensor 94 is mainly exemplified in the form of a pressure sensor, which can be analogically referred to for other forms of sensors, and the present disclosure will not describe each of them in detail.

As illustrated in FIG. 4, the second sensor 50 may be a mass flow sensor, and may be disposed in the second flow channel 300 to collect the vacuum flow rate in the second flow channel 300.

The regulating valve 80 may be a piezoelectric proportional valve, and the controller 90 regulates an opening degree of the piezoelectric proportional valve by adjusting a duty ratio thereof.

When the regulating valve 80 is a piezoelectric proportional valve, the controller 90 may store a correspondence between the duty ratio and the opening degree of the piezoelectric proportional valve. When comparing the target vacuum flow rate value with the vacuum flow rate detected by the second sensor 50 and determining that a difference therebetween is greater than a preset difference, the controller 90 may regulate an opening degree of the regulating valve 80 based on the signal detected by the first sensor 94 and a current opening degree of the regulating valve 80, until the difference is within a preset difference range. The specific value of the preset difference is not specifically limited herein. Theoretically, it would be better for the actual vacuum flow rate value detected by the second sensor 50 to be closer to the target vacuum flow rate value, and ideally, the two may be identical. However, since different application environments have different requirements for regulation accuracy and regulation efficiency, the preset difference may be controlled within a certain range to meet the use requirements.

In the embodiments, the controller 90 may be integrated in the housing 10. Specifically, the controller 90 may include a circuit board disposed close to one side of the housing 10. Specifically, the circuit board may be in the form of a PCB board, and of course, other forms are feasible. The controller 90 may be connected to the first sensor 94, the second sensor 50 and the regulating valve 80 through a wire connection or a wireless connection.

In some other embodiments, it is not excluded to dispose the controller 90 outside the housing 10 or to share an existing controller, etc. The specific position and form of the controller 90 may be set according to actual needs, which are not specifically limited herein.

In addition, a first dip switch 92 and a second dip switch 93 are disposed on a side of the housing 10 close to the circuit board for switching between different signal input and output modes. Specifically, the first dip switch 92 and the second dip switch 93 may have different states, which may be varied depending on the form of the signal. For example, when a digital signal is received, the first dip switch 92 and the second dip switch 93 may be in a first state, and when an analog signal is received, the first dip switch 92 and the second dip switch 93 may be in a second state.

In the embodiments, the housing 10 is provided therein with a first flow channel 200 and a second flow channel 300, which may be formed by hollow connecting members, by casting inside the housing 10, or by any other process.

Referring to FIG. 4, in the embodiments of the present disclosure, the first flow channel 200 and the second flow channel 300 are mainly exemplified in the form of connecting members, which may be analogically referred to for other forms of sensors, and the present disclosure will not describe each of them in detail.

Specifically, a first connecting member 20 is disposed in the housing 10, and a hollow cavity is provided in the first connecting member 20 to form the first flow channel 200. A position detected by the first sensor 94 is located upstream of the regulating valve 80 in a fluid flowing direction.

Referring to FIGS. 2 and 6, the first flow channel 200 has a first starting end 21 for being connected to a positive pressure gas source, and a first terminating end 24. Specifically, the first starting end 21 may be connected to the external positive pressure gas source through a sealed connection. The sealed connection may be a threaded sealing. For example, the first starting end 21 is provided with sealing internal threads, and correspondingly, a connection port of the positive pressure air source is provided with sealing external threads for fitting with the sealing internal threads. In addition, the specific form of the sealed connection is not specifically limited herein. Being taught by the technical essence of the present disclosure, those skilled in the art can make other changes, which should fall within the scope of the present disclosure as long as the achieved functions and effects are the same or similar to those of the present disclosure.

The position detected by the first sensor 94 is located upstream of the regulating valve 80 and close to the first starting end 21, so as to accurately detect the pressure of the gas supplied by the external positive pressure gas source.

Referring to FIGS. 4 and 5, specifically, a branch flow channel 22 in communication with the first flow channel 200 is disposed in the first connecting member 20. An open end of the branch flow channel 22 is in communication with the first flow channel 200, and the other end thereof is a closed end. The first sensor 94 is mounted in the branch flow channel 22 by means of sealing.

During flowing, the gas entering from the first starting end 21 first flows through the upstream branch flow channel 22, at which time the first sensor 94 (e.g., a pressure sensor) may be used to collect the pressure data and transmit it to the circuit board. A detection portion of the pressure sensor may protrude into the branch flow channel 22. A main portion of the pressure sensor may be sealed and fixed by a first sealing ring 23, without affecting the sealing of the other end of the branch flow channel 22. The main portion of the pressure sensor may be disposed close to the circuit board or directly mounted on the circuit board, thereby further improving the integration of the vacuum mass flow control apparatus.

In an embodiment, a second connecting member 70 is disposed in the housing 10, and the first connecting member 20 is in communication with the regulating valve 80 through the second connecting member 70.

Specifically, the second connecting member 70 may be a structure which has a hollow chamber formed inside and which may be close to the first terminating end 24 of the first flow channel 200. The second connecting member 70 is mainly used to connect the regulating valve 80 into the first flow channel 200 to regulate the opening degree of the first flow channel 200, thereby changing parameters such as the pressure and the flow rate of fluid in the first flow channel 200. The regulating valve 80 may be disposed close to the circuit board, or integrally mounted on the circuit board, so as to further improve the integration of the vacuum mass flow control apparatus.

In an embodiment, a third connecting member 30 may be disposed in the housing 10, a hollow cavity is formed in the third connecting member 30 to form the second flow channel 300, and the second sensor 50 is disposed in the second flow channel 300.

Specifically, the third connecting member 30 may be disposed at a side away from the circuit board relative to the first connecting member 20. A hollow cavity is formed in the third connecting member 30 to form the second flow channel 300. The second flow channel 300 has a second starting end 31 for being connected to a peripheral device, and a second terminating end. Specifically, the second starting end 31 may be connected to the peripheral device by a sealed connection. The sealed connection may be a threaded sealing. For example, the second starting end 31 is provided with sealing internal threads, and correspondingly, a connection port of the peripheral device is provided with sealing external threads for fitting with the sealing internal threads. In addition, the specific form of the sealed connection is not specifically limited herein. Being taught by the technical essence of the present disclosure, those skilled in the art can make other changes, which should fall within the scope of the present disclosure as long as the achieved functions and effects are the same or similar to those of the present disclosure.

The second sensor 50 (e.g., a mass flow sensor) is disposed in the second flow channel 300. Specifically, the second sensor 50 may have an inlet and an outlet opposite to each other, both of which are in sealed connections in the second flow channel 300. The second sensor 50 may be electrically connected to the circuit board, and specifically, may be connected by a wire harness 40. In order to avoid the wire harness 40 and provide a restraining space therefor, grooves 41 for avoiding and positioning the wire harness 40 may be disposed on outer surfaces of the first connecting member 20 and the third connecting member 30.

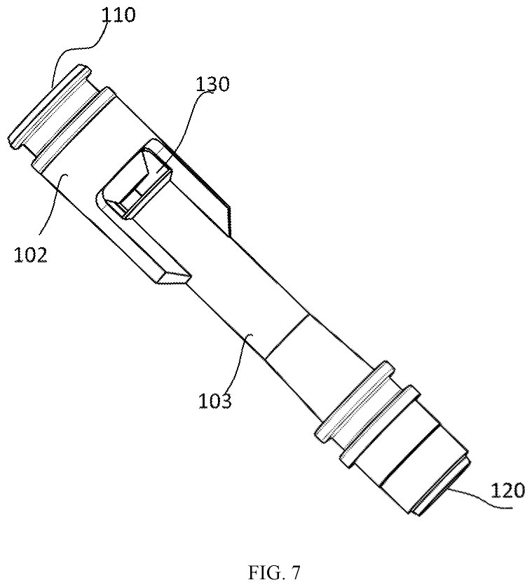

Referring to FIGS. 6 and 7, in an embodiment, a fourth connecting member 60 may be disposed in the housing 10. A hollow main cavity 61 and a bypass cavity 62 in communication with the main cavity 61 are formed in the fourth connecting member 60. The main cavity 61 is connected to the first terminating end 24 of the first flow channel 200 and used to mount the venturi tube 100 by sealing. The bypass cavity 62 is connected to the second terminating end of the second flow channel 300.

In the embodiments, the venturi tube 100 is mounted in the fourth connecting member 60, and mainly used to merge the first flow channel 200 and the second flow channel 300. Specifically, the fourth connecting member 60 includes the main cavity 61 for mounting the venturi tube 100, and the bypass cavity 62 in communication with the main cavity 61.

The main cavity 61 has an inlet side and an outlet side opposite to each other, and the inlet side may be in sealed connection with the first terminating end 24 of the first flow channel 200. Specifically, the sealed connection may be made by disposing a second sealing ring 63 between the first terminating end 24 and the inlet side of the main cavity 61. Of course, the specific form of the sealed connection is not specifically limited herein. Being taught by the technical essence of the present disclosure, those skilled in the art can make other changes, which should fall within the scope of the present disclosure as long as the achieved functions and effects are the same or similar to those of the present disclosure.

The venturi tube 100 has an inlet end 110 and an outlet end 120 opposite to each other and a negative pressure suction port 130. The inlet end 110 of the venturi tube 100 is located at the inlet side of the main cavity 61 and opposite to the first terminating end 24 for receiving the positive pressure gas flowing from the first terminating end 24. The outlet end 120 of the venturi tube 100 is located at the outlet side of the main cavity 61 which allows the merged fluid to flow out. Specifically, the fluid flowing out may flow into a recovery device or directly discharged to the outside, which is varied depending on the specific composition and production requirement of the fluid, and is not specifically limited herein. The negative pressure suction port 130 of the venturi tube 100 is located at a tube section with a smaller inner diameter in the middle of the venturi tube 100. The negative pressure suction port 130 may be in communication with the second terminating end of the second flow channel 300 through the bypass cavity 62, so that a negative pressure gas flow can be formed in the second flow channel 300.

It should be noted here that the bypass cavity 62 specifically may be a cavity structure with a certain length. Of course, alternatively, the bypass cavity 62 may be a bypass port in the main cavity 61, and at this case, a cavity portion of the bypass cavity 62 may be formed by a portion of the second flow channel 300 close to the second terminating end. In a specific embodiment, the venturi tube 100 includes a first portion 102 and a second portion 103 which are sealedly disposed in the main cavity 61, with a converge gap formed between the first portion 102 and a second portion 103. The converge gap is opposite to the bypass cavity 62.

In the embodiments, the venturi tube 100 may specifically include the first portion 102 and the second portion 103 sealedly disposed in the main cavity 61. The sealing may be made by a sealing ring, and of course in any other way, which is not specifically limited herein. In addition, in order to effectively limit the sealing ring and facilitate the mounting and dismounting of the venturi tube 100, a snap 101 may be disposed between the main cavity 61 and the first terminating end 24.

As illustrated in FIG. 7, the first portion 102 is provided with the inlet end 110 at one end, and the second portion 103 is provided with an outlet end 120 at one end. The first portion 102 and the second portion 103 may be connected to each other by threads, so as to realize the relative fixation thereof. Of course, the relative fixation may also be realized by means of other connection modes, such as a snap connection, etc. The specific connection mode between the first portion 102 and the second portion 103 is not specifically limited herein. A converge gap is formed between the first portion 102 and the second portion 103 and may be opposite to the bypass cavity 62. The converge gap serves as the negative pressure suction port 130 of the venturi tube 100. When the positive pressure gas flow supplied from the first flow channel 200 flows through the main cavity 61, a negative pressure is formed in the converge gap and causes the gas flow in the second flow channel 300 to flow.

It should be noted that since a middle portion of the venturi tube 100 with a smaller inner diameter has a certain length, an annular gap is formed between the portion and the main cavity 61, so that the fluid flows into the annular gap will eventually flow out of the converge gap through the outlet side.

Further, a flow-through cross-sectional area of the first terminating end 24 may be smaller than that of the bypass cavity 62, and larger than a minimum flow-through cross-sectional area of the venturi tube 100.

The first terminating end 24 serves as a port of the positive pressure flow channel. Firstly, the positive pressure gas flow flowing out of the first terminating end 24 flows into the venturi tube 100, and then the negative pressure gas flow is formed in the bypass cavity 62 and flows into the venturi tube 100. In addition, a minimum flow-through cross-sectional area of the venturi tube 100 is the smallest of the entire internal flow channel, which is smaller than the flow-through cross-sectional area of the first terminating end 24 and the flow-through cross-sectional area of the bypass cavity 62, thereby achieving a strong negative pressure adsorption at the minimum flow-through cross-sectional area.

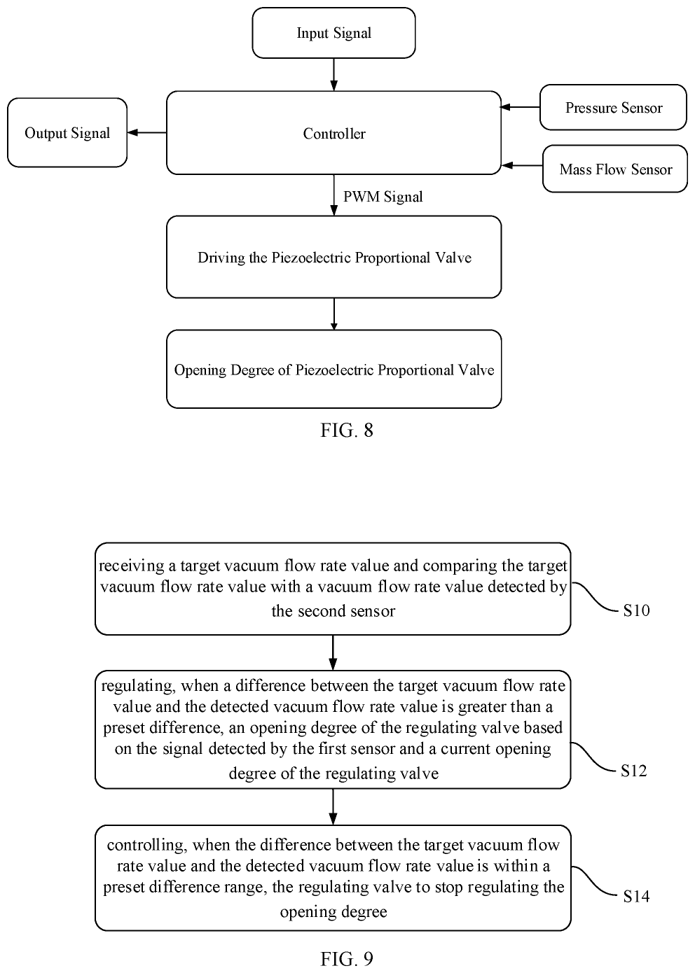

Referring to FIGS. 8 and 9, based on the vacuum mass flow control apparatus according to the above embodiments, embodiments of the present disclosure further provides a vacuum mass flow control method, which may include the following steps:
step S10: receiving a target vacuum flow rate value, and comparing the target vacuum flow rate value with a vacuum flow rate value detected by the second sensor 50;
step S12: regulating, when a difference between the target vacuum flow rate value and the detected vacuum flow rate value is greater than a preset difference, an opening degree of the regulating valve 80 based on the signal detected by the first sensor 94 and a current opening degree of the regulating valve 80;
step S14: controlling, when the difference between the target vacuum flow rate value and the detected vacuum flow rate value is within a preset difference range, the regulating valve 80 to stop regulating the opening degree.

In the embodiments, an exemplary illustration may be given with the first sensor 94 being a pressure sensor, the second sensor 50 being a mass flow sensor, and the regulating valve 80 being a piezoelectric proportional valve.

The step of regulating the opening degree of the regulating valve 80 based on the signal detected by the first sensor 94 and the current opening degree of the regulating valve includes: sending, by the controller 90, a PWM drive signal to the piezoelectric proportional valve; regulating the opening degree of the piezoelectric proportional valve by regulating a duty ratio of the piezoelectric proportional valve.

In a specific scenario, the controller 90 may receive a target vacuum flow rate value sent by a client and compare the received target vacuum flow rate value with a current vacuum flow rate detected by the mass flow sensor. If a difference between the target vacuum flow rate value and the detected vacuum flow rate value is greater than a preset difference, it means that the current vacuum flow rate needs to be regulated by the regulating valve 80. During regulation, a PWM signal may be sent to the piezoelectric proportional valve based on a current pressure of the pressure sensor and a current opening degree of the piezoelectric proportional valve, so as to drive the piezoelectric proportional valve to undergo an opening degree adjustment. The controller 90 may store a correspondence between a duty ratio and an opening degree of the piezoelectric proportional valve. During regulation, the opening degree of the piezoelectric proportional valve may be regulated by changing the duty ratio thereof, so as to make the current vacuum flow rate value approaches the target vacuum flow rate value, i.e., the difference between the detected vacuum flow rate value and the target vacuum flow rate value is within a preset difference range

The specific value of the preset difference is not specifically limited herein. Theoretically, it would be better for the actual vacuum flow rate value detected by the second sensor to be closer to the target vacuum flow rate value, and ideally, the two may be identical. However, since different application environments have different requirements for regulation accuracy and regulation efficiency, the preset difference may be controlled within a certain range to meet the use requirements.

All articles and references disclosed, including patent applications and publications, are hereby incorporated by reference for all purposes. The term ‘substantially composed of . . . ’ used to describe a combination should include the determined elements, compositions, components or steps as well as other elements, compositions, components or steps that do not substantively affect the basic novel features of the combination. The use of the term ‘include’ or ‘comprise’ to describe a combination of elements, compositions, components or steps herein also contemplates the embodiments substantially constituted by these elements, compositions, components or steps. Herein the use of the term ‘may’ is intended that any described attribute included by ‘may’ is optional. A plurality of elements, compositions, components or steps can be provided by a single integrated element, composition, component or step. Alternatively, a single integrated element, composition, component or step may be divided into separate elements, compositions, components or steps. The disclosure ‘a’ or ‘an’ used to describe an element, composition, component or step is not intended to exclude other elements, compositions, components or steps.

Each embodiment in the present disclosure is described in a progressive manner. Each embodiment lays an emphasis on its difference from other embodiments, and the same or similar parts of the embodiments can refer to each other. The above embodiments are only used to describe the technical ideas and characteristics of the present disclosure, and the purpose is to allow those skilled in the art to understand the contents of the present disclosure and implement them accordingly, rather than limiting the protection scope of the present disclosure. Any equivalent change or modification made according to the spirit essence of the present disclosure should fall within the protection scope of the present disclosure.

What is claimed is:

1. A vacuum mass flow control apparatus, comprising:
a housing (10);
a first flow channel (200) disposed in the housing (10), and having a first starting end (21) for being connected to a positive pressure gas source and a first terminating end (24);
a first sensor (94) for collecting a signal of fluid in the first flow channel (200);
a second flow channel (300) disposed in the housing (10), and having a second starting end (31) for being connected to a peripheral device and a second terminating end;
a second sensor (50) for collecting a vacuum flow rate in the second flow channel (300);
a venturi tube (100) having an inlet end (110), an outlet end (120) and a negative pressure suction port (130), wherein when a positive pressure fluid flowing out of the first terminating end (24) flows through the venturi tube (100) via the inlet end (110), it sucks a negative pressure fluid at the second terminating end into the venturi tube (100) via the negative pressure suction port (130) and then flows out with the negative pressure fluid via the outlet end (120);
a regulating valve (80) for regulating a flow-through cross-sectional area of the first flow channel (200); and
a controller (90) electrically connected to the regulating valve (80), the first sensor (94) and the second sensor (50).

2. The vacuum mass flow control apparatus according to claim 1, wherein the controller (90) is configured to:
receive a target vacuum flow rate value, and compare the target vacuum flow rate value with a vacuum flow rate value detected by the second sensor (50);
regulate, when a difference between the target vacuum flow rate value and the detected vacuum flow rate value is greater than a preset difference, an opening degree of the regulating valve (80) based on the signal collected by the first sensor (94) and a current opening degree of the regulating valve (80), until the difference is within a preset difference range.

3. The vacuum mass flow control apparatus according to claim 2, wherein the first sensor (94) is a pressure sensor, the regulating valve (80) is a piezoelectric proportional valve, and the controller (90) regulates the opening degree of the piezoelectric proportional valve by regulating a duty ratio of the piezoelectric proportional valve.

4. The vacuum mass flow control apparatus according to claim 1, wherein a first connecting member (20) is disposed in the housing (10), a hollow cavity is provided in the first connecting member (20) to form the first flow channel (200), and a position detected by the first sensor (94) is located upstream of the regulating valve (80) in a fluid flowing direction.

5. The vacuum mass flow control apparatus according to claim 4, wherein a branch flow channel (22) in communication with the first flow channel (200) is disposed in the first connecting member (20);
an open end of the branch flow channel (22) is in communication with the first flow channel (200), and the other end thereof is a closed end; and
the first sensor (94) is mounted in the branch flow channel (22) by means of sealing.

6. The vacuum mass flow control apparatus according to claim 4, wherein a second connecting member (70) is disposed in the housing (10), and the first connecting member (20) is in communication with the regulating valve (80) through the second connecting member (70).

7. The vacuum mass flow control apparatus according to claim 1, wherein a third connecting member (30) is disposed in the housing (10), a hollow cavity is provided in the third connecting member (30) to form the second flow channel (300), and the second sensor (50) is disposed in the second flow channel (300).

8. The vacuum mass flow control apparatus according to claim 1, wherein a fourth connecting member (60) is disposed in the housing (10);
a hollow main cavity (61) and a bypass cavity (62) in communication with the main cavity (61) are provided in the fourth connecting member (60); and
the main cavity (61) is connected to the first terminating end (24) of the first flow channel (200), and the venturi tube (100) is sealingly mounted in the main cavity (61), and the bypass cavity (62) is connected to the second terminating end of the second flow channel (300).

9. The vacuum mass flow control apparatus according to claim 8, wherein the venturi tube (100) comprises a first portion (102) and a second portion (103) which are sealingly disposed in the main cavity (61), with a converge gap formed therebetween and opposite to the bypass cavity (62).

10. The vacuum mass flow control apparatus according to claim 8, wherein a flow-through cross-sectional area of the first terminating end (24) is smaller than that of the bypass cavity (62) and larger than a minimum flow-through cross-sectional area of the venturi tube (100).

11. The vacuum mass flow control apparatus according to claim 1, wherein the controller (90) comprises a circuit board disposed close to one side of the housing (10), and the side of the housing (10) close to the circuit board is provided with a first dip switch (92) and a second dip switch (93) for switching between different signal input and output modes.

12. A vacuum mass flow control method based on the vacuum mass flow control apparatus according to claim 1, comprising:
receiving a target vacuum flow rate value and comparing the target vacuum flow rate value with a vacuum flow rate value detected by the second sensor (50);
regulating, when a difference between the target vacuum flow rate value and the detected vacuum flow rate value is greater than a preset difference, an opening degree of the regulating valve (80) based on the signal detected by the first sensor (94) and a current opening degree of the regulating valve (80); and
controlling, when the difference is within a preset difference range, the regulating valve (80) to stop regulating the opening degree.

13. The vacuum mass flow control method according to claim 12, wherein the first sensor (94) is a pressure sensor, and the regulating valve (80) is a piezoelectric proportional valve; and
the step of regulating the opening degree of the regulating valve (80) based on the signal detected by the first sensor (94) and the current opening degree of the regulating valve (80) comprises:
sending, by the controller (90), a PWM drive signal to the piezoelectric proportional valve; and
regulating the opening degree of the piezoelectric proportional valve by regulating a duty ratio of the piezoelectric proportional valve.
